(19) United States
(12) Patent Application Publication
(10) Pub. No.: US 2024/0334716 A1
(43) Pub. Date: Oct. 3, 2024

(54) SEMICONDUCTOR DEVICES AND DATA STORAGE SYSTEMS INCLUDING THE SAME

(71) Applicant: SAMSUNG ELECTRONICS CO., LTD., Suwon-si (KR)

(72) Inventors: Moorym Choi, Suwon-si (KR); Seungwoo Paek, Suwon-si (KR); Sunil Shim, Suwon-si (KR); Yunsun Jang, Suwon-si (KR)

(21) Appl. No.: 18/417,970

(22) Filed: Jan. 19, 2024

(30) Foreign Application Priority Data
Mar. 27, 2023 (KR) 10-2023-0039736

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80006; H01L 2224/80895; H01L 2224/80896; H01L 2924/1431; H01L 2924/14511

(57) ABSTRACT

A semiconductor device includes a first semiconductor structure including circuit elements on a first substrate, a lower interconnection structure on the circuit elements, and a lower bonding structure on the lower interconnection structure; and a second semiconductor structure including a second substrate on the first semiconductor structure, separation insulating patterns separating the second substrate, and disposed to be spaced apart from each other, gate electrodes stacked to be spaced apart from each other, separation regions passing through the gate electrodes, and disposed to be spaced apart from each other, channel structures passing through the gate electrodes, an upper interconnection structure below the gate electrodes, and an upper bonding structure bonded to the lower bonding structure, wherein the separation insulating patterns include first separation insulating patterns on the separation regions, and second separation insulating patterns between the channel structures and passing through the second substrate.

### CROSS-REFERENCE TO RELATED APPLICATION(S)

This application claims the benefit of priority to Korean Patent Application No. 10-2023-0039736 filed on Mar. 27, 2023, in the Korean Intellectual Property Office, the subject matter of which is hereby incorporated by reference in its entirety.

### BACKGROUND

The present disclosure relates to a semiconductor device and a data storage system including the same.

In a data storage system requiring data storage, a semiconductor device for storing high-capacity data may be required. Accordingly, methods for increasing data storage capacity of semiconductor devices are being researched. For example, as a method for increasing data storage capacity of a semiconductor device, a semiconductor device including memory cells arranged three-dimensionally, instead of memory cells arranged two-dimensionally, has been proposed.

### SUMMARY

The present disclosure relates to providing a semiconductor device that is easy to manufacture and has improved electrical characteristics and reliability. Conventionally, manufacturing bit vector NAND (BVNAND) structures that include two or more semiconductor structures can include forming a string select line (SSL) cut region and a ground select line (GSL) region before bonding the two or more semiconductor structures. However, forming the SSL-cut region and the GSL-cut region before bonding the two or more semiconductor structures can increase process complexity and cost.

The present disclosure relates to a techniques that omit forming the SSL-cut region and the GSL-cut region, and instead include forming separation insulating patterns after bonding two or more semiconductor structures. Accordingly, in some implementations, the resulting semiconductor structure can have a high degree of integration and improved electrical characteristics with less process difficulty and a lower cost compared to conventional techniques. Additionally, in certain implementations, the techniques disclosed herein avoids the formation of channel-hole sidewall oxide-nitride-oxide (ONO) butting (CSOB).

In general, innovative aspects of the subject matter described in this specification can be embodied in a semiconductor device that includes: a first semiconductor structure including a first substrate, circuit elements on the first substrate, a lower interconnection structure electrically connected to the circuit elements, and a lower bonding structure electrically connected to the lower interconnection structure; and a second semiconductor structure including a second substrate on the first semiconductor structure, separation insulating patterns separating the second substrate, extending in a first direction, and disposed to be spaced apart from each other in a second direction, perpendicular to the first direction, gate electrodes stacked to be spaced apart from each other in a third direction, perpendicular to the first and second directions, separation regions passing through the gate electrodes, extending in the first direction, and disposed to be spaced apart from each other in the second direction, channel structures passing through the gate electrodes, extending in the third direction, and respectively including a channel layer, an upper interconnection structure below the gate electrodes and the channel structures, and an upper bonding structure connected to the upper interconnection structure and bonded to the lower bonding structure, wherein the separation insulating patterns include first separation insulating patterns connected to the separation regions, and second separation insulating patterns between the channel structures and passing through the second substrate.

Another general aspect can be embodied in a semiconductor device includes: a first semiconductor structure including a first substrate, circuit elements on the first substrate, a lower interconnection structure electrically connected to the circuit elements, and a lower bonding structure electrically connected to the lower interconnection structure; and a second semiconductor structure including a second substrate on the first semiconductor structure, separation insulating patterns separating the second substrate, extending in a first direction, and disposed to be spaced apart from each other in a second direction, perpendicular to the first direction, gate electrodes stacked to be spaced apart from each other in a third direction, perpendicular to the first and second directions, separation regions passing through the gate electrodes, extending in the first direction, and disposed to be spaced apart from each other in the second direction, channel structures passing through the gate electrodes, extending in the third direction, and respectively including a channel layer, an upper interconnection structure below the gate electrodes and the channel structures, and an upper bonding structure connected to the upper interconnection structure and bonded to the lower bonding structure, wherein the separation insulating patterns are between the channel structures, and are on the separation regions.

Another general aspect can be embodied in a data storage system that includes: a semiconductor storage device including a first semiconductor structure including a first substrate and circuit elements on the first substrate; a second semiconductor structure including a second substrate, gate electrodes spaced apart from each other and stacked below the second substrate, and channel structures passing through the gate electrodes; and an input/output pad electrically connected to the circuit elements; and a controller electrically connected to the semiconductor storage device through the input/output pad and controlling the semiconductor storage device, wherein the first semiconductor structure further includes a lower interconnection structure electrically connected to the circuit elements; and a lower bonding structure connected to the lower interconnection structure, wherein the second semiconductor structure further includes separation insulating patterns separating the second substrate, extending in a first direction, and spaced apart from each other in a second direction, perpendicular to the first direction separation regions passing through the gate electrodes, extending in the first direction, and spaced apart from each other in the second direction; an upper bonding structure bonded to the lower bonding structure; and an upper interconnection structure connected to the upper bonding structure, wherein the separation insulating patterns include first separation insulating patterns connected to the separation regions and second separation insulating patterns between the channel structures and passing through the second substrate.

### BRIEF DESCRIPTION OF THE DRAWINGS

FIG. 1 is a schematic exploded perspective view illustrating an example of a semiconductor device.

FIG. 2A is a schematic plan view of the semiconductor device of FIG. 1.

FIGS. 2B and 2C are schematic cross-sectional views of the semiconductor device of FIG. 1.

FIG. 2D is a partially enlarged cross-sectional view of the semiconductor device of FIG. 1.

FIG. 2E is a schematic circuit diagram of the semiconductor device of FIG. 1.

FIG. 3A is a schematic plan view of an example of a semiconductor device.

FIG. 3B is a schematic cross-sectional view of an example of a semiconductor device.

FIG. 3C is a partially enlarged cross-sectional view of an example of a semiconductor device.

FIGS. 4, 5 and 6 are partially enlarged cross-sectional views of examples of a semiconductor device.

FIG. 7A is a schematic plan view of an example of a semiconductor device.

FIG. 7B is a partially enlarged cross-sectional view of the semiconductor device of FIG. 7A.

FIG. 8 is a schematic cross-sectional view of an example of a semiconductor device.

FIGS. 9A, 9B, 9C, 9D, 9E, 9F, 9G, 9H, and 9I are schematic cross-sectional views illustrating an example of a method of manufacturing a semiconductor device.

FIG. 10 is a view schematically illustrating an example of a data storage system including a semiconductor device.

FIG. 11 is a perspective view schematically illustrating an example of a data storage system including a semiconductor device.

FIG. 12 is a schematic cross-sectional view of the semiconductor package of FIG. 11.

### DETAILED DESCRIPTION

Hereinafter, examples will be described with reference to the accompanying drawings. Hereinafter, it can be understood that terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated.

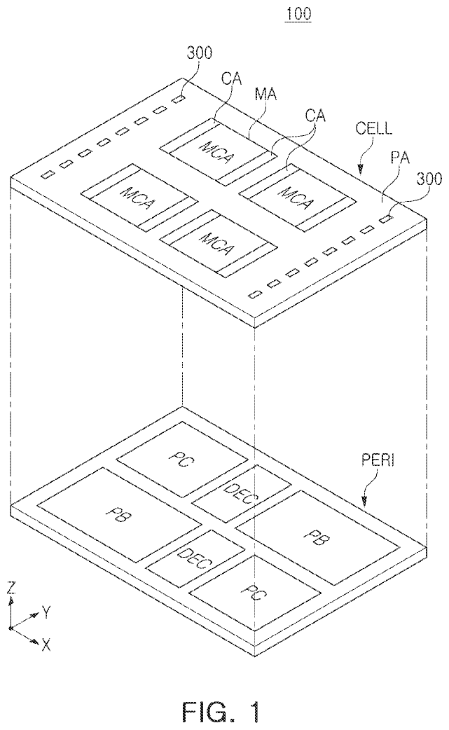

FIG. 1 is a schematic exploded perspective view illustrating an example of a semiconductor device 100. Referring to FIG. 1, the semiconductor device 100 may include a peripheral circuit region PERI and a memory cell region CELL, stacked in a vertical direction (a Z-direction). The peripheral circuit region PERI and the memory cell region CELL may be bonded and coupled. The memory cell region CELL may include a memory region MA including a memory cell array region MCA and a connection region CA, and an outer region PA disposed outside of the memory region MA. A conductive pad 300 as an input/output pad may be disposed on the outer region PA. A plurality of memory regions MA including the memory cell array region MCA and the connection region CA may be disposed.

The peripheral circuit region PERI may include a row decoder DEC, a page buffer PB, and a peripheral circuit PC. In the peripheral circuit region PERI, the row decoder DEC may decode an input address, to generate and transfer driving signals of a word line. The page buffer PB may be connected to the memory cell array region MCA through bit lines, to read information stored in memory cells. The peripheral circuit PC may be a region including a control logic and a voltage generator, and may include, for example, a latch circuit, a cache circuit, and/or a sense amplifier. The peripheral circuit region PERI may further include a separate pad region. In this case, the separate pad region may include an electrostatic discharge (ESD) device or a data input/output circuit. The ESD device or data input/output circuit of the pad region may be electrically connected to the conductive pad 300 of the outer region PA. Various circuit regions DEC, PB, and PC in the peripheral circuit region PERI may be arranged in various forms.

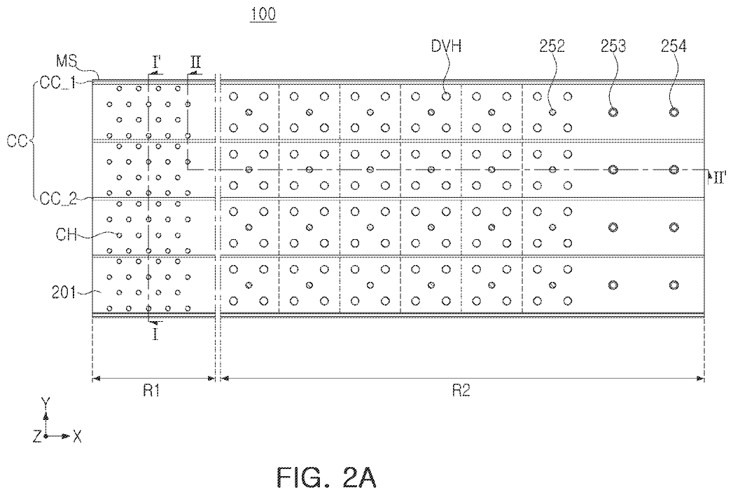

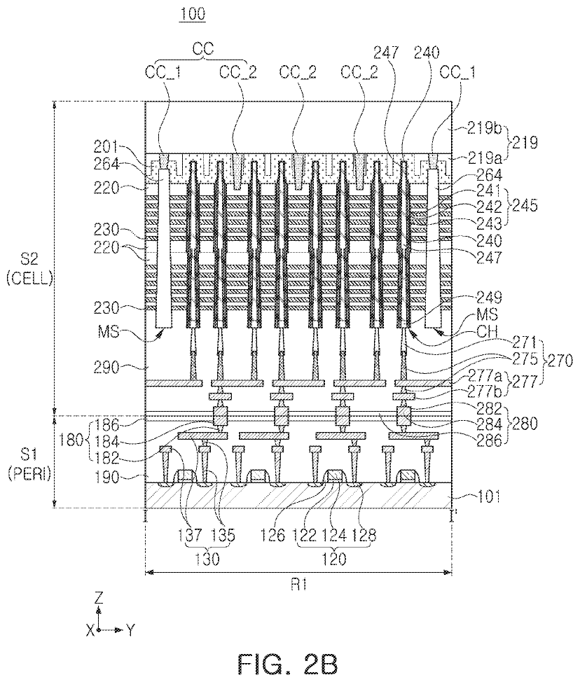

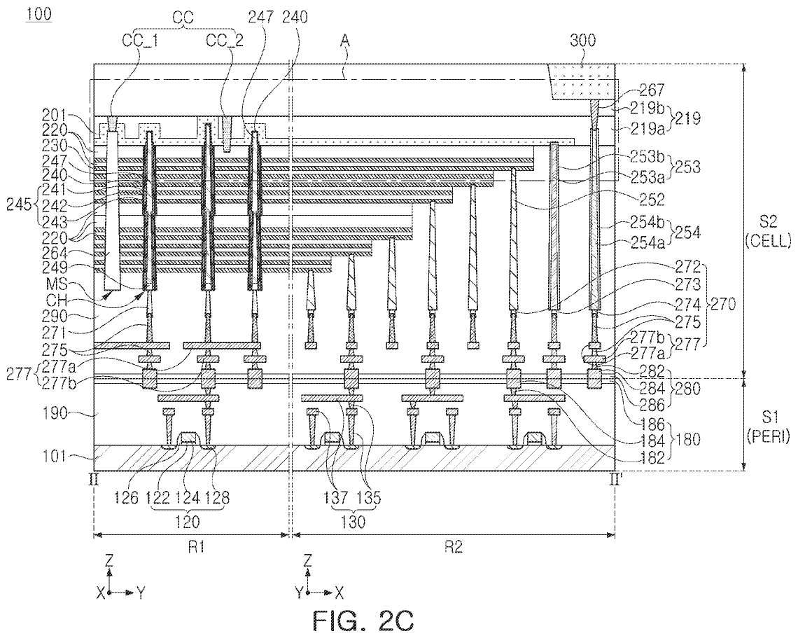

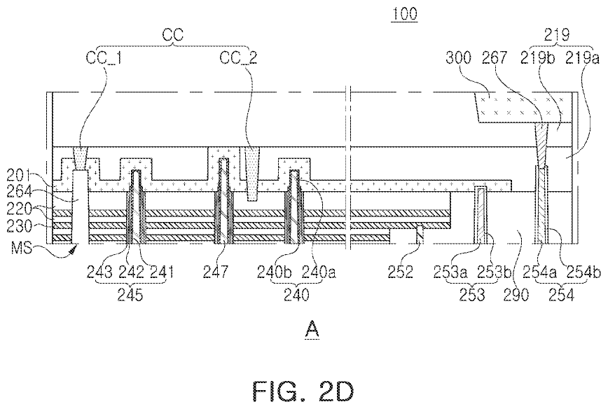

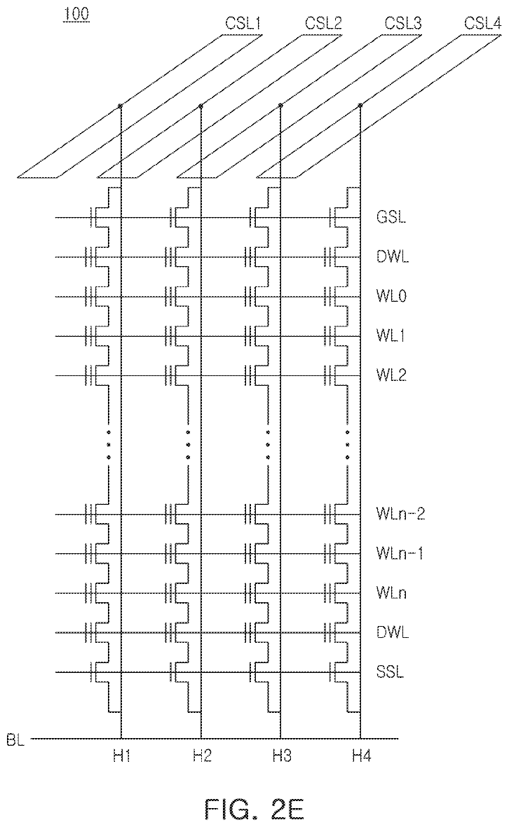

Hereinafter, an example of the semiconductor device 100 will be described with reference to FIGS. 2A to 2E. In FIGS. 2A and 2C, a first region R1 may correspond to the memory cell array region MCA illustrated in FIG. 1, and a second region R2 may correspond to the connection region CA and the outer region PA illustrated in FIG. 1.

FIG. 2A is a schematic plan view of the semiconductor device 100 of FIG. 1. FIGS. 2B and 2C are schematic cross-sectional views of the semiconductor device 100. FIG. 2D is a partially enlarged cross-sectional view of the semiconductor device 100. FIGS. 2B and 2C illustrate cross-sections of FIG. 2A, taken along lines I-I′ and II-II′, respectively. FIG. 2D is an enlarged view of portion ‘A’ of FIG. 2C.

Referring to FIGS. 2A, 2B, 2C and 2D, the semiconductor device 100 includes a peripheral circuit region PERI and a memory cell region CELL. The memory cell region CELL may be disposed on the peripheral circuit region PERI. The peripheral circuit region PERI and the memory cell region CELL may be bonded to each other by bonding structures 180 and 280. The peripheral circuit region PERI may be referred to as a first semiconductor structure S1, and the memory cell region CELL may be referred to as a second semiconductor structure S2.

The peripheral circuit region PERI may include a first substrate 101, circuit elements 120 on the first substrate 101, a lower interconnection structure 130, a lower bonding structure 180, and a lower capping layer 190.

The first substrate 101 may include a semiconductor material, for example, a group IV semiconductor, a group III-V compound semiconductor, or a group II-VI compound semiconductor. The first substrate 101 may be provided as a bulk wafer or an epitaxial layer. An active region may be defined on the first substrate 101 by device isolation layers. Source/drain regions 128 containing impurities may be disposed in a portion of the active region. In the implementations described in this disclosure, the phrase source/drain region may be understood to mean a source terminal region or a drain terminal region of a transistor.

The circuit elements 120 may include a transistor. Each of the circuit elements 120 may include a circuit gate dielectric layer 122, a circuit gate electrode 124, and a source/drain region 128. Source/drain regions 128 including impurities may be disposed in the first substrate 101 on both sides of the circuit gate electrode 124. Spacer layers 126 may be disposed on both sides of the circuit gate electrode 124. The circuit gate dielectric layer 122 may include silicon oxide, silicon nitride, or a high-k material. The circuit gate electrode 124 may be formed of titanium nitride (TiN), tantalum nitride (TaN), tungsten nitride (WN), titanium silicon nitride (TiSiN), tantalum silicon nitride (TaSiN), tungsten silicon nitride (WSiN), tungsten (W), copper (Cu), aluminum (Al), molybdenum (Mo), or ruthenium (Ru). The circuit gate electrode 124 may include a semiconductor layer, for example a doped polycrystalline silicon layer. In some implementations, the circuit gate electrode 124 is formed as two or more multilayer structures.

The lower interconnection structure 130 may be electrically connected to the circuit gate electrodes 124 and the source/drain regions 128 of the circuit elements 120. The lower interconnection structure 130 may include lower contact plugs 135 having a cylindrical shape or a truncated cone shape, and lower interconnection lines 137 in which at least one region has a linear shape. Portions of the lower contact plugs 135 may be connected to the source/drain regions 128, and although not illustrated, different portions of the lower contact plugs 135 may be connected to the circuit gate electrodes 124. The lower contact plugs 135 may electrically connect the lower interconnection lines 137, disposed on different levels from an upper surface of the first substrate 101, to each other. The lower interconnection structure 130 may include a conductive material, may include, for example, tungsten (W), copper (Cu), aluminum (Al), or the like, and each component thereof may further include a diffusion barrier layer including at least one of titanium (Ti), titanium nitride (TiN), tantalum (Ta), tantalum nitride (TaN), or tungsten nitride (WN). In some implementations, the number of layers and arrangement of the lower contact plugs 135 and the lower interconnection lines 137, constituting the lower interconnection structure 130, may be variously changed.

The lower bonding structure 180 may be connected to the lower interconnection structure 130. The lower bonding structure 180 may include a lower bonding via 182, a lower bonding pad 184, and a lower bonding insulating layer 186. The lower bonding via 182 may be connected to the lower interconnection structure 130. The lower bonding pad 184 may be connected to the lower bonding via 182. The lower bonding via 182 and the lower bonding pad 184 may include a conductive material, may include, for example, tungsten (W), copper (Cu), aluminum (Al), or the like, respectively, and each component thereof may further include a diffusion barrier layer, respectively. The lower bonding insulating layer 186 may also function as a diffusion barrier layer of the lower bonding pad 184, and may include at least one of SiCN, SiO, SIN, SiOC, SiON, or SiOCN. The lower bonding insulating layer 186 may have a thickness, thinner than a thickness of the lower bonding pad 184, but is not limited thereto. The lower bonding structure 180 may be bonded or connected to an upper bonding structure 280 by direct contact with the upper bonding structure 280 through hybrid bonding. For example, the lower bonding pad 184 may be coupled to an upper bonding pad 284 by contact with the upper bonding pad 284 through copper-to-copper bonding, and the lower bonding insulating layer 186 may be coupled to an upper bonding insulating layer 286 by contact with the upper bonding insulating layer 286 through dielectric-to-dielectric bonding. The lower bonding structure 180, together with the upper bonding structure 280, may provide an electrical connection path between the peripheral circuit region PERI and the memory cell region CELL.

The lower capping layer 190 may be disposed on the first substrate 101 to cover the circuit elements 120 and the lower interconnection structure 130. The lower capping layer 190 may include a plurality of insulating layers. The lower capping layer 190 may include an insulating material such as silicon oxide, silicon nitride, silicon oxynitride, silicon oxycarbide, or the like.

The memory cell region CELL may include a second substrate 201, separation insulating patterns CC separating the second substrate 201, gate electrodes 230 stacked below the second substrate 201, separation regions MS extending through a stack structure of the gate electrodes 230, channel structures CH disposed to pass through the stack structure, contact plugs 252, 253, and 254 for electrical connection with the peripheral circuit region PERI, an upper interconnection structure 270 below the stack structure, and an upper bonding structure 280 connected to the upper interconnection structure 270.

The memory cell region CELL may further include interlayer insulating layers 220 alternately stacked with the gate electrodes 230 below the second substrate 201, dummy vertical structures DVH in the second region R2, a peripheral contact via 267 on a peripheral contact plug 254 among the contact plugs 252, 253, and 254, an upper capping layer 290 covering the stack structure, an upper insulating layer 219 contacting an external end portion of the second substrate 201 and disposed on the substrate 201, and a conductive pad 300 on the peripheral contact via 267.

The memory cell region CELL may be defined by a first region R1 corresponding to a memory cell array region MCA, and a second region R2 corresponding to a connection region CA and an outer region PA.

As illustrated in FIG. 2B, the first region R1 may be a region in which the gate electrodes 230 are spaced apart from each other and stacked in the vertical direction, for example, the Z-direction, and the channel structures CH are disposed. As illustrated in FIG. 2C, the second region R2 may be a region in which the gate electrodes 230 extend to have different lengths, to provide contact pads for electrically connecting memory cells to the peripheral circuit region PERI. Also, the second region R2 may be a region in which a source contact plug 253 is disposed. The second region R2 may further include a region ranging from the external end portion of the second substrate 201 to an edge of the semiconductor device 100. For example, a region in which the conductive pad 300 and the peripheral contact plug 254 are disposed may be included. It can be understood that the first region R1 and the second region R2 are regions including the second substrate 201 and including a region below the second substrate 201 and a region above the second substrate 201.

The second substrate 201 may include a semiconductor material, for example, a group IV semiconductor, a group III-V compound semiconductor, or a group II-VI compound semiconductor. For example, the group IV semiconductor may include silicon (Si), germanium (Ge), or silicon-germanium (SiGe). The second substrate 201 may function as a common source line of the semiconductor device 100. For example, the second substrate 201 may include, but is not limited to, a doped polysilicon layer having an N-type conductivity. In some implementations, the second substrate 201 may be formed to conformally cover the channel structures CH and the source contact plug 253, but is not limited thereto.

The separation insulating patterns CC may separate the second substrate 201 into multiple sections, may extend in the X-direction, and may be spaced apart from each other in a Y-direction, perpendicular to the X-direction. The separation insulating patterns CC may be disposed parallel to each other. The separation insulating patterns CC may include first separation insulating patterns CC_1 passing through the second substrate 201 and connected to the separation regions MS, and second separation insulating patterns CC_2 disposed between the channel structures CH and passing through the second substrate 201.

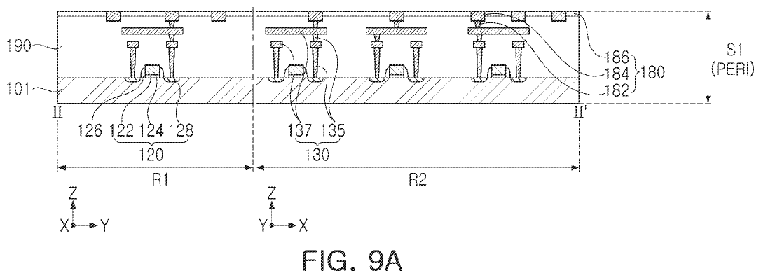

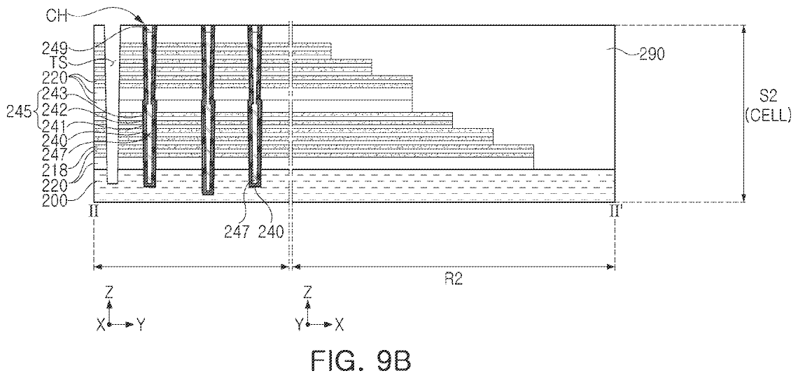

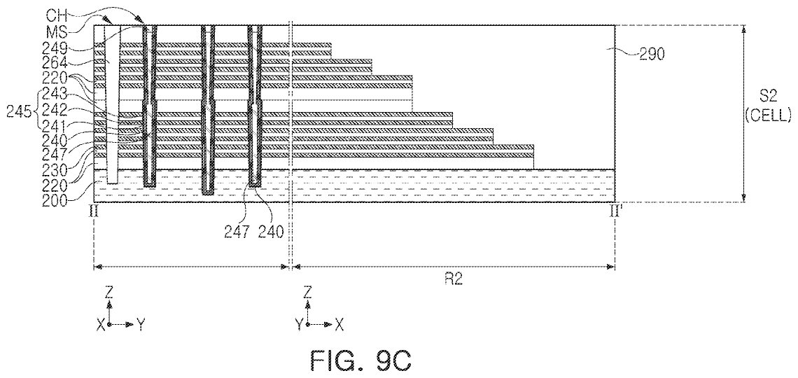

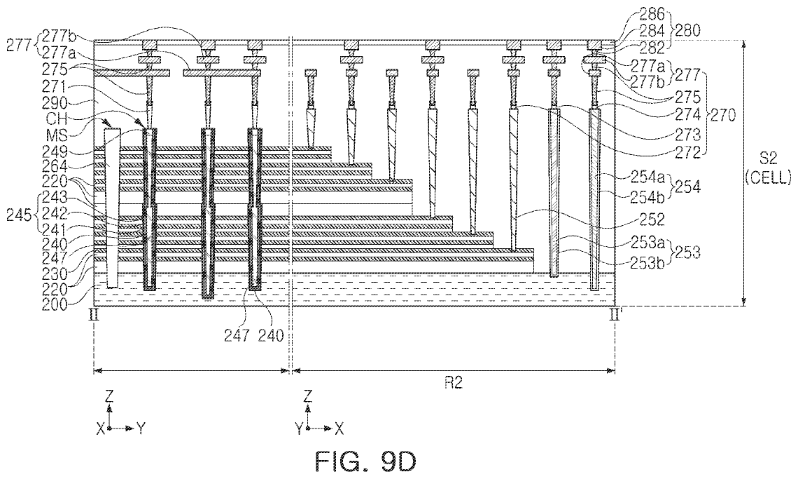

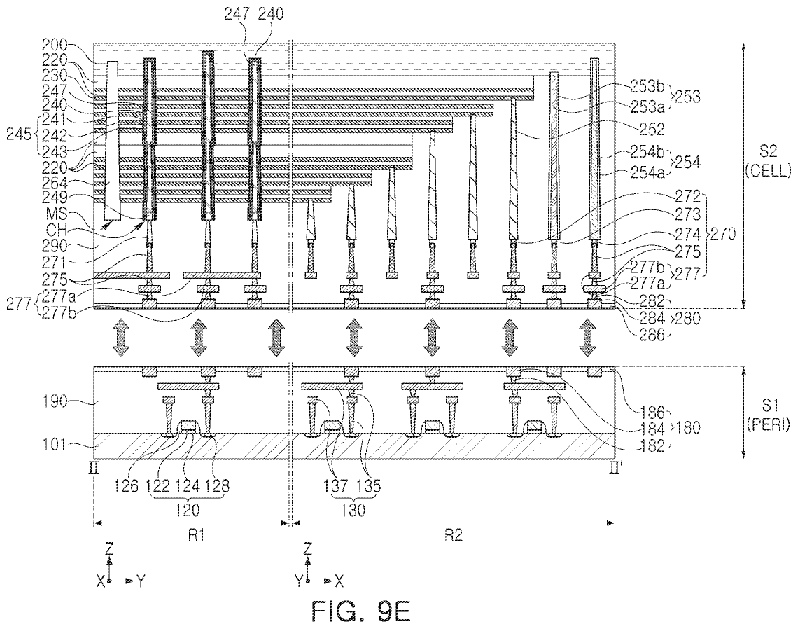

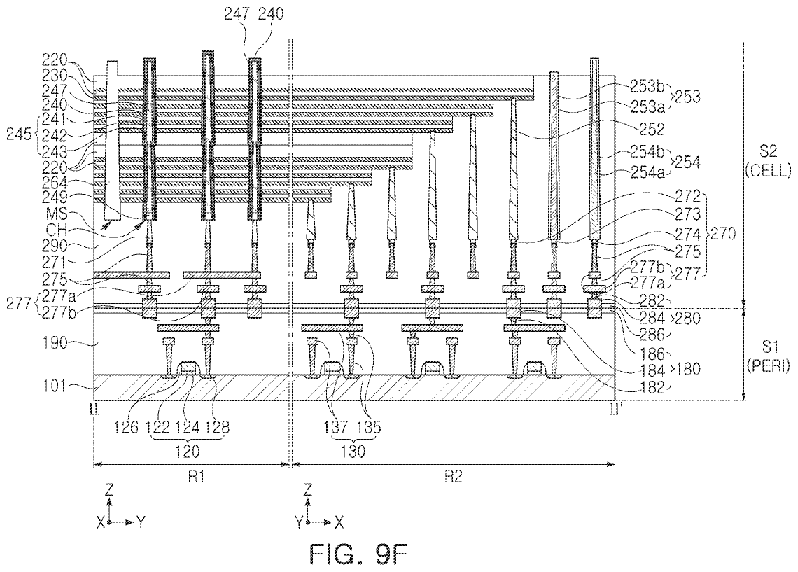

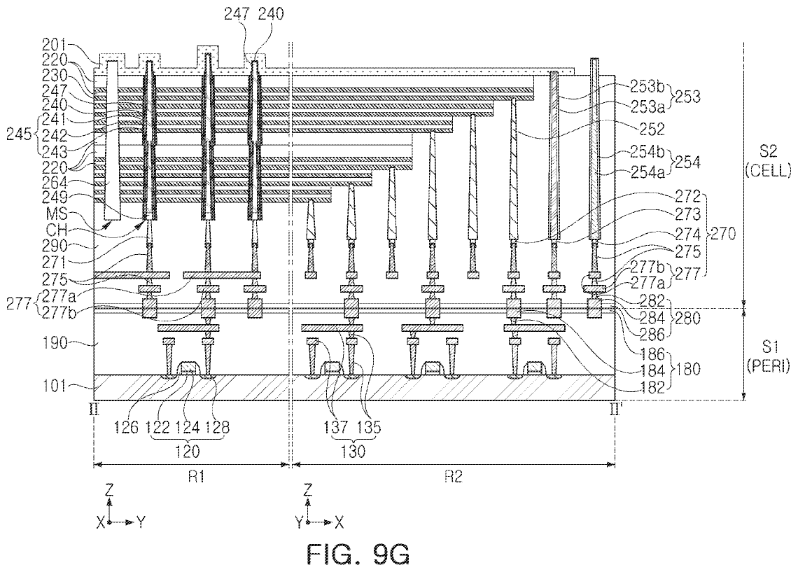

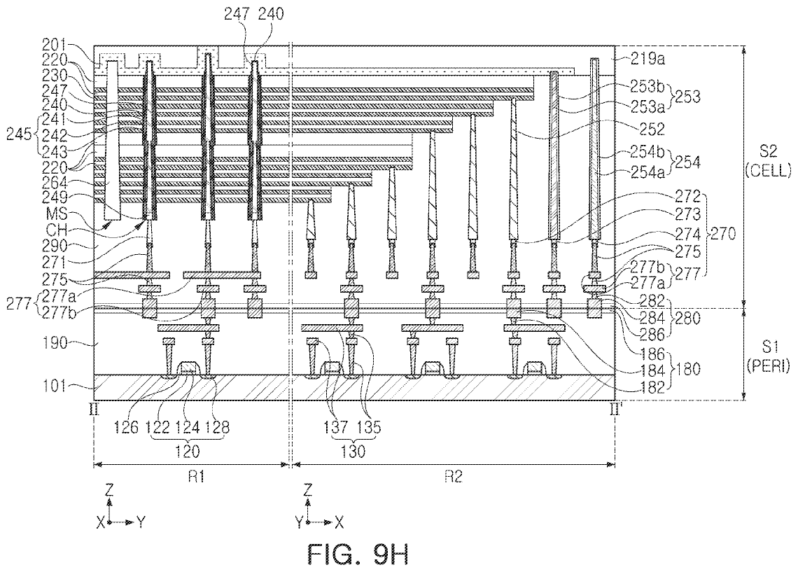

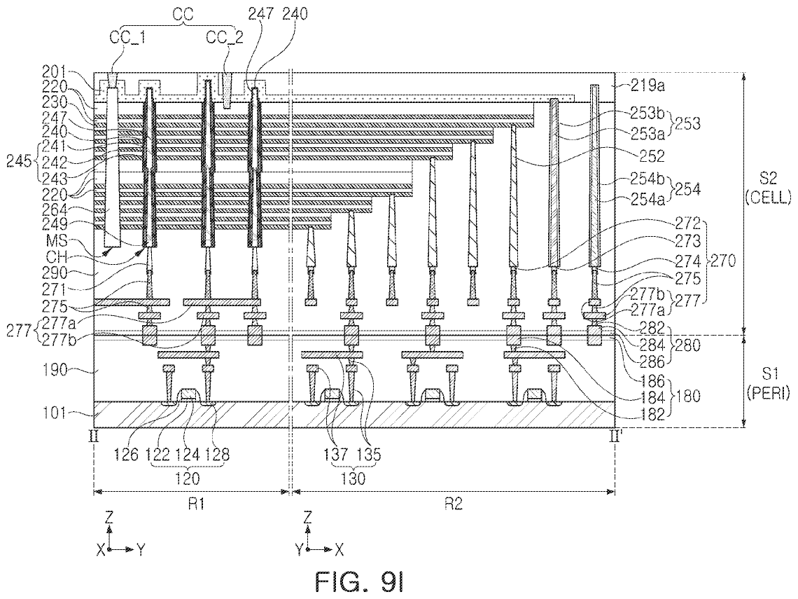

A level of at least one upper surface among upper surfaces of the first separation insulating patterns CC_1 may be substantially equal to a level of at least one upper surface among upper surfaces of the second separation insulating patterns CC_2. In this disclosure, substantially equal to means two values are 1 within 5% of each other. The levels being substantially equal to each other may be due to a process of FIG. 9H to be described later. A level of at least one lower surface among lower surfaces of the first separation insulating patterns CC_1 may be located to be higher than a level of at least one lower surface among lower surfaces of the second separation insulating patterns CC_2, but is not limited thereto. Levels of the lower surfaces of the second separation insulating patterns CC_2 may be substantially equal to or lower than a level of a lower surface of the second substrate 201. Due to this, the second substrate 201 may be separated. In some implementations, the lower surfaces of the second separation insulating patterns CC_2 may be disposed on a level, lower than an upper surface of a channel layer 240, and may be disposed on a level, lower than an uppermost end of a channel dielectric layer 245. The upper surfaces of the first separation insulating patterns CC_1 and the upper surfaces of the second separation insulating patterns CC_2 may be disposed on a level, higher than an uppermost end of the channel layer 240.

In some implementations, since the source contact plug 253 may be in contact with the second substrate 201 on an upper end of the source contact plug 253, and the second separation insulating patterns CC_2 may pass through the second substrate 201 and may extend below the lower surface of the second substrate 201, lowermost ends of the second separation insulating patterns CC_2 may be disposed on a level, lower than an uppermost end of the source contact plug 253.

In some implementations, the upper surfaces of the first separation insulating patterns CC_1 and the upper surfaces of the second separation insulating patterns CC_2 may be located on a level, substantially equal to a level of at least a portion of the upper surface of the second substrate 201, and the lower surfaces of the separation insulating patterns CC_2 may be located on a level, lower than the lower surface of the second substrate 201.

The first separation insulating patterns CC_1 may separate the second substrate 201 on the separation regions MS, and the second separation insulating patterns CC_2 may separate the second substrate 201 between the channel structures CH. In some implementations, the second substrate 201 and each of the separation insulating patterns CC may be alternately disposed in the Y-direction. Therefore, a process of forming an insulating region separating a string select line (SSL, see FIG. 2E) from common source lines CSL1, CSL2, CSL3, and CSL4 and a process of forming an insulating region separating a ground select line (GSL, see FIG. 2E) from common source lines CSL1, CSL2, CSL3, and CSL4 in the gate electrodes 230 may be omitted. Therefore, in some implementations, a degree of integration as well as electrical characteristics of the semiconductor device are improved, and the complexity of the fabrication process can be reduced.

The gate electrodes 230 may be vertically spaced apart and stacked below the second substrate 201 to form a stack structure. The gate electrodes 230 may be disposed between the second substrate 201 and the upper interconnection structure 270. The gate electrodes 230 may include electrodes sequentially forming a ground select transistor, memory cells, and a string select transistor from the second substrate 201. The number of gate electrodes 230 constituting the memory cells may be determined according to storage capacity of the semiconductor device 100. In some implementations, the number of gate electrodes 230 constituting the string select transistor and the ground select transistor is one or two or more, respectively, and the gate electrodes 230 have the same structure as or a different structure from the gate electrodes 230 of the memory cells. In addition, the gate electrodes 230 may be disposed below a gate electrode 230 constituting the string select transistor and above a gate electrode 230 constituting the ground select transistor, and may further include a gate electrode 230 constituting an erase transistor used for an erase operation using a gate induced drain leakage (GIDL) phenomenon.

The gate electrodes 230 may be spaced apart from each other and stacked in the vertical direction in the memory cell array region MCA, and may extend to have different lengths from the memory cell array region MCA to the connection region CA to have a stepped structure. As illustrated in FIG. 2C, the gate electrodes 230 may have a stepped structure in the X-direction, and may be arranged to have a stepped structure in the Y-direction as well. Due to the stepped structure, the gate electrodes 230 may form a stepped shape in which the upper gate electrode 230 extends longer than the lower gate electrode 230, and may form end portions exposed from the interlayer insulating layers 220 toward the first substrate 101. In the end portions, the gate electrodes 230 may have increases in thickness.

The gate electrodes 230 may form a lower gate stack group and an upper gate stack group on the lower gate stack group. The interlayer insulating layer 220 disposed between the lower gate stack group and the upper gate stack group may have a relatively thick thickness, but is not limited thereto. FIG. 2A illustrates that two stack groups of gate electrodes 230 are arranged vertically, but is not limited thereto, and the gate electrodes 230 may be also formed as a single stack group or a plurality of stack groups.

The gate electrodes 230 may include a metal material, such as tungsten (W). In some implementations, the gate electrodes 230 may include polycrystalline silicon or a metal silicide material. In some implementations, the gate electrodes 230 may further include a diffusion barrier layer. For example, the diffusion barrier layer may be formed of tungsten nitride (WN), tantalum nitride (TaN), titanium nitride (TiN), or a combination thereof.

The gate electrodes 230 may be disposed such that at least a portion of the gate electrodes 230 is separated in a predetermined unit by the separation regions MS in the Y-direction. Gate electrodes 230 between a pair of adjacent separation regions MS may form a memory block, but the form of the memory block is not limited thereto.

The interlayer insulating layers 220 may be disposed between the gate electrodes 230. Like the gate electrodes 230, the interlayer insulating layers 220 may be spaced apart from each other in a direction, perpendicular to a lower surface of the second substrate 201, and may be disposed to extend in the X-direction. The interlayer insulating layers 220 may include an insulating material such as silicon oxide or silicon nitride.

The separation regions MS may be disposed to pass through the gate electrodes 230 in the memory cell array region MCA and connection region CA and to extend in the Z-direction. The separation regions MS may extend in the X-direction to separate the gate electrodes 230 from each other in the Y-direction. The separation regions MS may be disposed apart from each other in the Y-direction, and may be disposed parallel to each other. The separation regions MS may be disposed parallel to the separation insulating patterns CC. The separation region MS may pass through entirely the gate electrodes 230 stacked below the second substrate 201, and may be connected to the first separation insulating patterns CC_1. A separation insulating layer 264 may be disposed in the separation regions MS. The separation region MS may have a shape in which a width decreases toward the second substrate 201 due to a high aspect ratio, but is not limited thereto. A conductive layer may be further disposed in the separation insulating layer 264 in the separation regions MS. The separation insulating layer 264 may include an insulating material such as silicon oxide or silicon nitride, and may include, for example, silicon oxide, silicon nitride, or silicon oxynitride. In some implementations, the disposition order, the number, or other features of separation regions MS are not limited to those illustrated in FIG. 2A.

The channel structures CH may form a memory cell string, respectively, and may be spaced apart from each other while forming rows and columns in the memory cell array region MCA. The channel structures CH may be arranged to form a lattice pattern in an X-Y plane or may be arranged to have a zigzag shape in one direction. The channel structures CH may pass through the gate electrodes 230, may extend in a vertical direction, perpendicular to the lower surface of the second substrate 201, for example, in the Z-direction, may have a columnar shape, and may have a side surface having a decrease in width toward the second substrate 201, depending on an aspect ratio.

Each of the channel structures CH may have a form in which lower and upper channel structures passing through the lower gate stack group and the upper gate stack group of gate electrodes 230 are connected to each other, and may have a bent portion by a difference in width or a change in width.

The channel layer 240 may be disposed in the channel structures CH. The channel layer 240 may be connected between the lower channel structure and the upper channel structure. The channel layer 240 may include protrusions 240a and non-protrusions 240b of the channel layer 240. Lengths of protrusions 240a that protrude from the channel structures CH may not be equal to each other, but are not limited thereto. The channel layer 240 may be formed to have an annular shape surrounding a channel filling insulating layer 247 therein, but may have a column shape such as a cylinder or a prism without the channel filling insulating layer 247. The channel layer 240 may be in contact with the second substrate 201. For example, the protrusion 240a of the channel layer 240 may be connected to the second substrate 201 in an upper portion of the channel layer 240. The channel layer 240 may include a semiconductor material such as polycrystalline silicon or single crystal silicon, and the semiconductor material may be an undoped material or a material containing p-type or n-type impurities. In some implementations, an upper end of the channel layer 240 may be in contact with the second substrate 201.

Channel pads 249 may be disposed on a lower portion of the channel layer 240 in the channel structures CH. The channel pads 249 may cover a lower surface of the channel filling insulating layer 247, and may be electrically connected to the channel layer 240. The channel pads 249 may include, for example, doped polycrystalline silicon.

The channel dielectric layer 245 may be disposed between the gate electrodes 230 and the channel layer 240. The channel dielectric layer 245 may include a tunneling layer 241, a charge storage layer 242, and a blocking layer 243, sequentially stacked from the channel layer 240. The tunneling layer 241 may tunnel charges into the charge storage layer 242, and may include, for example, silicon oxide (SiO₂), silicon nitride (Si₃N₄), silicon oxynitride (SiON), or a combination thereof. The charge storage layer 242 may be a charge trap layer or a floating gate conductive layer. The blocking layer 243 may include silicon oxide (SiO₂), silicon nitride (Si₃N₄), silicon oxynitride (SiON), a high-K dielectric material, or a combination thereof. In some implementations, at least a portion of the channel dielectric layer 245 may extend in a horizontal direction along the gate electrodes 230.

The dummy vertical structures DVH may be disposed in the second region R2, and may have the same or similar structure as the channel structures CH, but may not perform a substantial function in the semiconductor device 100. The dummy vertical structures DVH may be regularly arranged in rows and columns in the second region R2. The dummy vertical structures DVH may have a diameter, longer than a maximum diameter of the gate contact plugs 252. The shape, number and/or spacing of the dummy vertical structures DVH may be different. The channel structures CH and the dummy vertical structures DVH may have a circular shape or a nearly circular shape, but is not limited thereto, and may have an elliptical shape.

Each of the contact plugs 252, 253, and 254 may have a cylindrical shape or a truncated cone shape, and may have a decrease in width in an upward direction according to an aspect ratio. The contact plugs 252, 253, and 254 may pass through a portion of the upper capping layer 290. The contact plugs 252, 253, and 254 may include a gate contact plug 252, a source contact plug 253, and a peripheral contact plug 254. The gate contact plug 252, the source contact plug 253, and the peripheral contact plug 254 may be spaced apart from each other, and may be disposed in plurality, respectively. Each of the contact plugs 252, 253, and 254 may include a conductive layer and a barrier layer surrounding side surfaces and one end of the conductive layer, respectively. For example, as illustrated in FIG. 2B, the contact plugs 253 and 254 may include conductive layers 253a and 254a and barrier layers 253b and 254b, and the barrier layers 253b and 254b may surround upper and side surfaces of the conductive layers 253a and 254a. The conductive layers 253a and 254a may include a conductive material, and may include, for example, a metal material such as tungsten (W), copper (Cu), or aluminum (Al), and the barrier layers 253b and 254b may include, for example, at least one of titanium (Ti), titanium nitride (TiN), tantalum (Ta), tantalum nitride (TaN), tungsten nitride (WN), or tungsten carbon nitride (WCN).

The gate contact plugs 252 may be disposed in the second region R2, and may extend in a vertical direction, for example, in the Z-direction. The gate contact plugs 252 may be respectively connected to contact pads or end portions of the gate electrodes 230, having a stepped shape. The gate contact plugs 252 may be connected to the upper interconnection structure 270 through a lower portion of the gate contact plugs 252.

The source contact plug 253 may extend in a vertical direction, for example, in the Z-direction. In some implementations, the source contact plug 253 may be disposed to partially recess the second substrate 201, and may be connected to the second substrate 201. Based on the upper surface of the first substrate 101, a lower surface of the source contact plug 253 may be located on a level, lower than a lowest gate electrode 230 among the gate electrodes 230. For example, the source contact plug 253 may extend from a level, lower than the lowest gate electrode 230 closest to the first semiconductor structure S1, among the gate electrodes 230, to at least an internal space of the second substrate 201. The lower surface of the source contact plug 253 may be connected to the upper interconnection structure 270. A width of an upper surface of the source contact plug 253 may be less than a width of a lower surface of the source contact plug 253. The source contact plug 253 may be formed in the same process as the peripheral contact plug 254, and may have the same or similar shape as the peripheral contact plug 254.

The peripheral contact plug 254 may be spaced apart from the second substrate 201 and the source contact plug 253, on an outside of the second substrate 201, and may extend in a vertical direction, for example, in the Z-direction. The peripheral contact plug 254 may be connected to the upper interconnection structure 270. An upper surface of the peripheral contact plug 254 may be located on a level, higher than the upper surface of the source contact plug 253, but is not limited thereto.

The upper interconnection structure 270 may electrically connect the gate electrodes 230, the channel structures CH, the second substrate 201, and the conductive pad 300, to the circuit elements 120. The upper interconnection structure 270 may include a channel contact plug 271, a gate contact stud 272, a source contact stud 273, a peripheral contact stud 274, an upper contact plug 275, and an upper interconnection line 277. The channel contact plug 271 may be connected to the channel pad 249 of the channel structure CH. The channel contact plug 271 may be electrically connected to the channel layer 240 through the channel pads 249 of the channel structures CH in the memory cell array region MCA. The gate contact stud 272 may be connected to the gate contact plug 252. The source contact stud 273 may be connected to the source contact plug 253. The peripheral contact stud 274 may be connected to the peripheral contact plug 254. Upper contact plugs 275 may be connected to the channel contact plug 271, the gate contact stud 272, the source contact stud 273, and the peripheral contact stud 274, respectively. The upper interconnection line 277 may be connected to the upper contact plug 275. The upper interconnection structure 270 may include a conductive material, and may include, for example, tungsten (W), copper (Cu), aluminum (Al), or the like, and each component thereof may further include a diffusion barrier layer including at least one of titanium (Ti), titanium nitride (TiN), tantalum (Ta), tantalum nitride (TaN), or tungsten nitride (WN). In some implementations, the number of layers and arrangement of upper contact plugs 275 and upper interconnection lines 277, constituting the upper interconnection structure 270, may be variously changed.

The upper bonding structure 280 may be connected to the upper interconnection structure 270. For example, the gate contact stud 272 and the channel contact plug 271 may be electrically connected to the upper bonding structure 280. The upper bonding structure 280 may include an upper bonding via 282, an upper bonding pad 284, and an upper bonding insulating layer 286. The upper bonding via 282 may be connected to the upper interconnection structure 270. The upper bonding pad 284 may be connected to the upper bonding via 282. The upper bonding via 282 and the upper bonding pad 284 may include a conductive material, may include, for example, tungsten (W), copper (Cu), aluminum (Al), or the like, and each component thereof may further include a diffusion barrier layer. The upper bonding insulating layer 286 may also function as a diffusion barrier layer of the upper bonding pad 284 and may include at least one of SiCN, SiO, SiN, SiOC, SiON, or SiOCN. The upper bonding insulating layer 286 may have a thickness, thinner than a thickness of the upper bonding pad 284, but is not limited thereto.

A width of a lower region of the peripheral contact via 267 may be less than a width of an upper region of the peripheral contact via 267. In some implementations, the peripheral contact via 267 may be in contact with the peripheral contact plug 254. The peripheral contact via 267 may include aluminum (Al). The peripheral contact via 267 may be connected to the conductive pad 300. The peripheral contact via 267 may include a plurality of vias connected to the conductive pad 300. The peripheral contact via 267 may be formed of a metal material, and may include, for example, tungsten (W) or aluminum (Al).

The upper capping layer 290 may be disposed below the second substrate 201, to cover the second substrate 201, the first upper insulating layer 219a, and the gate electrodes 230. The upper capping layer 290 may include a plurality of insulating layers. The upper capping layer 290 may include an insulating material such as silicon oxide, silicon nitride, silicon oxynitride, silicon oxycarbide, or the like.

The upper insulating layer 219 may be disposed on the second substrate 201. The upper insulating layer 219 may include a first upper insulating layer 219a covering the second substrate 201 and the peripheral contact via 267, and a second upper insulating layer 219b covering the conductive pad 300. The upper insulating layer 219 may include an insulating material such as silicon oxide, silicon nitride, silicon oxynitride, silicon oxycarbide, or the like.

The conductive pad 300 may be disposed on the upper insulating layer 219. The conductive pad 300 may be disposed on the peripheral contact plug 254, and may be electrically connected to the peripheral contact plug 254. The conductive pad 300 may be an input/output pad of the semiconductor device 100, and may be electrically connected to a controller. The conductive pad 300 may be disposed on the peripheral contact via 267, and the conductive pad 300 may be in contact with the peripheral contact via 267. The conductive pad 300 may be electrically connected to the circuit elements 120 of the peripheral circuit region PERI. The conductive pad 300 may include a conductive material, for example aluminum (Al).

FIG. 2E is a schematic circuit diagram of a semiconductor device 100. Referring to FIGS. 2B and 2E, the semiconductor device 100 may include first to fourth common source lines CSL1 to CSL4, a ground select line GSL, word lines WL0 to WLn, and a bit line BL. At least one dummy line DWL or at least one buffer line may be further disposed between an uppermost word line WL0 of the word lines WL0 to WLn and a string select line SSL. In some implementations, at least one dummy line DWL may also be disposed between a lowermost word line WLn and the ground select line GSL.

A first upper interconnection line 277a may be the bit line BL. A second substrate 201 may include the first to fourth common source lines CSL1 to CSL4. Channel structures CH may include first to fourth strings H1 to H4. The first to fourth strings H1 to H4 of the channel structures CH may be selected by an electrical signal applied to the bit line BL, and the first string H1 among the first to fourth strings H1 to H4 may be selected by an electrical signal applied to the first common source line CSL1. In this case, a program inhibit state may be maintained in the second to fourth strings H2 to H4 by electrical signals applied to the second to fourth common source lines CSL2 to CSL4.

In the description of the following examples, the same reference numerals as those of FIGS. 1 to 2E indicate corresponding configurations, and descriptions overlapping those described above will be omitted.

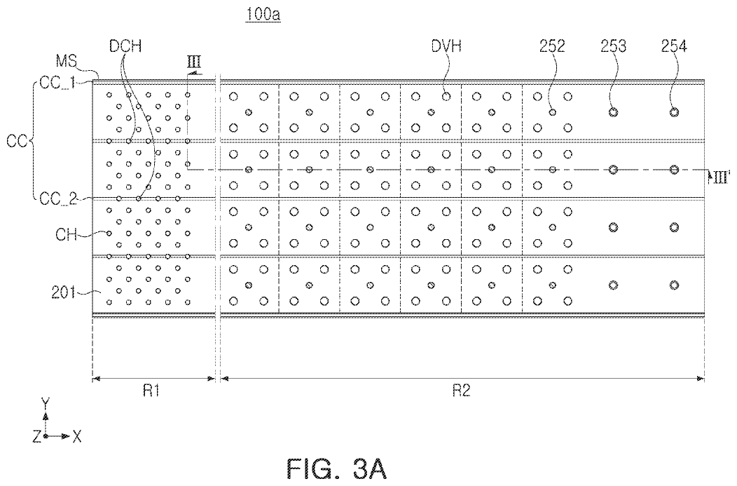

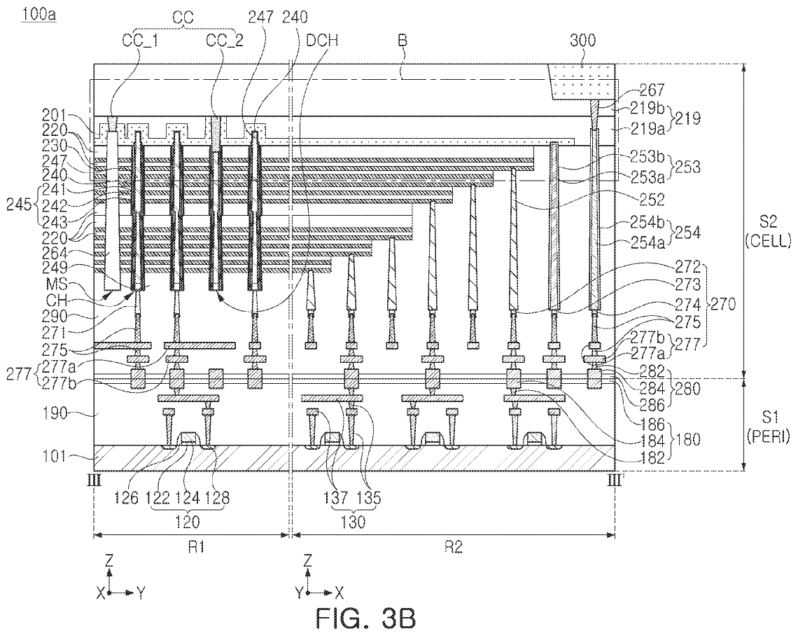

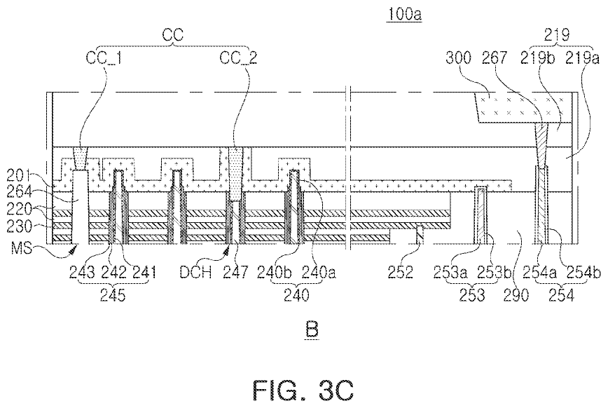

FIG. 3A is a schematic plan view of a semiconductor device 100a. FIG. 3B is a schematic cross-sectional view of the semiconductor device 100a. FIG. 3C is a partially enlarged cross-sectional view of the semiconductor device 100a. FIG. 3B illustrates a cross-section of FIG. 3A, taken along line III-III′. FIG. 3C is an enlarged view of portion ‘B’ of FIG. 3B.

Referring to FIGS. 3A to 3C, the semiconductor device 100a may further include dummy channel structures DCH passing through gate electrodes 230 in a first region R1 and extending in the Z-direction. In some implementations, the dummy channel structures DCH may be electrically separated from a second substrate 201 by second separation insulating patterns CC_2. For example, a width of each of the second separation insulating patterns CC_2 in the Y-direction may be greater than a diameter of each of the dummy channel structures DCH. In some implementations, the second separation insulating patterns CC_2 may pass through at least a portion of the dummy channel structures DCH to electrically separate the same from the second substrate 201. Channel contact plugs 271 may not be disposed on a dummy channel structure DCH. Alternatively, the channel contact plugs 271 may be disposed on the dummy channel structure DCH, and may not be connected to an upper interconnection line 277.

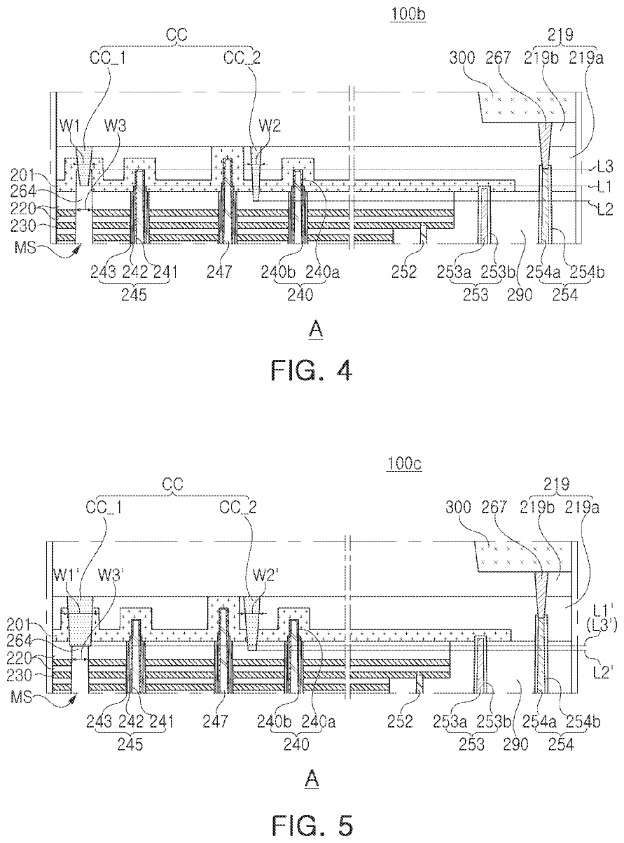

FIGS. 4, 5 and 6 are partially enlarged cross-sectional views of a semiconductor device 100b. FIGS. 4, 5 and 6 illustrate portions corresponding to those of FIG. 2D.

Referring to FIG. 4, in the semiconductor device 100b, portions of separation insulating patterns CC may pass through at least a portion of separation regions MS, and remaining portions of the separation insulating patterns CC may be spaced apart from a channel layer 240 between channel structures CH. For example, first separation insulating patterns CC_1 may pass through at least a portion of the separation regions MS, and second separation insulating patterns CC_2 may pass through a second substrate 201 between the channel structures CH, and may be disposed spaced apart from the channel layer 240.

A width W1 of each of the first separation insulating patterns CC_1 may be different from a width W2 of each of the second separation insulating patterns CC_2. In some implementations, a first width W1, which is the width W1 of the first separation insulating patterns CC_1 in the Y-direction, may be greater than a second width W2, which is the width W2 of the second separation insulating patterns CC_2 in the Y-direction, but is not limited thereto. In some implementations, a third width W3, which is a width W3 of the separation regions MS in the Y-direction, may be substantially equal to or greater than the first width W1.

In some implementations, the first separation insulating patterns CC_1 may pass through the second substrate 201, and the first separation insulating patterns CC_1 may pass through at least a portion of the separation regions MS. For example, a level L1 of a lower surface of each of the first separation insulating patterns CC_1 may be higher than a level L2 of a lower surface of each of the second separation insulating patterns CC_2, and may be lower than a level of an upper surface of each of the separation regions MS, but are not limited thereto, and the level L1 of the lower surface of each of the first separation insulating patterns CC_1 may be located on a level, lower than a lower surface of the second substrate 201. Therefore, the level L1 of the lower surface of the first separation insulating patterns CC_1 may be located on a level, substantially equal to the level L2 of the lower surface of each of the second separation insulating patterns CC_2.

A comparison of widths between each of the first separation insulating patterns CC_1, each of the second separation insulating patterns CC_2, and each of the separation regions MS may be independent of a comparison of positional relationships between upper surfaces and/or lower surfaces between each of the first separation insulating patterns CC_1, each of the second separation insulating patterns CC_2, and each of the separation regions MS.

Referring to FIG. 5, in a semiconductor device 100c, a first width W1′ of respective first separation insulating patterns CC_1 may be greater than a third width W3′ of respective separation regions MS. In some implementations, a level L1′ of a lower surface of each of the first separation insulating patterns CC_1 may be substantially equal to a level L3′ of an upper surface of each of the separation regions MS. The level L1′ of the lower surface of each of the first separation insulating patterns CC_1 may be lower than a level of a lower surface of a second substrate 201, and may be lower than a level L2′ of a lower surface of respective second separation insulating patterns CC_2.

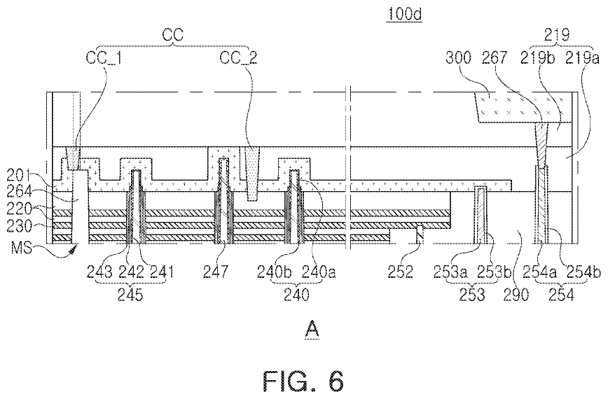

Referring to FIG. 6, in a semiconductor device 100d, central axes of first separation insulating patterns CC_1 and central axes of separation regions MS may be shifted. For example, the central axes of the first separation insulating patterns CC_1 and the central axes of the separation regions MS may be offset from each other. Even in the above case, the first separation insulating patterns CC_1 may be in contact with the separation regions MS to separate a second substrate 201.

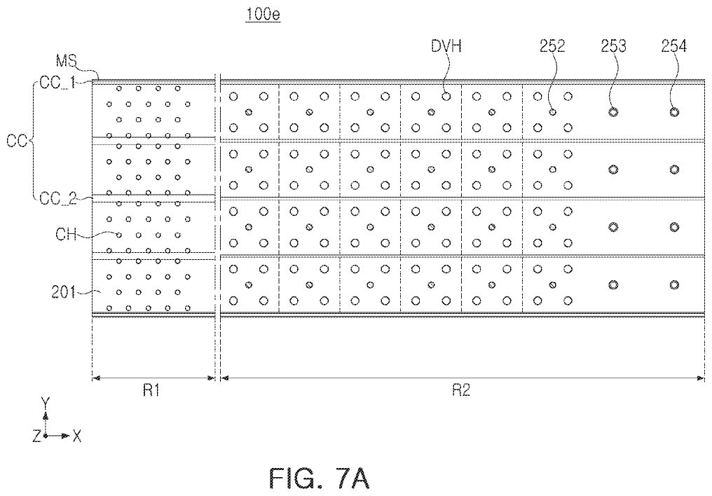

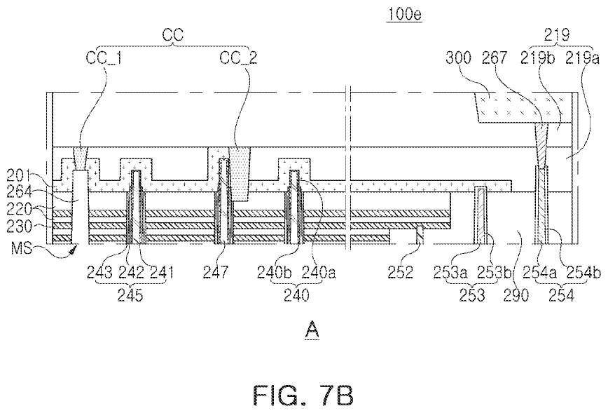

FIG. 7A is a schematic plan view of a semiconductor device 100e. FIG. 7B is a partially enlarged cross-sectional view of the semiconductor device 100e. FIG. 7B illustrates a portion corresponding to those of FIG. 2D.

Referring to FIGS. 7A and 7B, in the semiconductor device 100e, second separation insulating patterns CC_2 vertically overlap portions of channel structures CH. In some implementations, the second separation insulating patterns CC_2 includes a portion vertically overlapping a channel dielectric layer 245. The second separation insulating patterns CC_2 may be in contact with the channel dielectric layer 245, but may be spaced apart from a channel layer 240. A lower surface of each of the second separation insulating patterns CC_2 may be located on a level, lower than a lower surface of a second substrate 201. In some implementations, the second separation insulating patterns CC_2 may separate the second substrate 201 while contacting an upper portion of the channel dielectric layer 245.

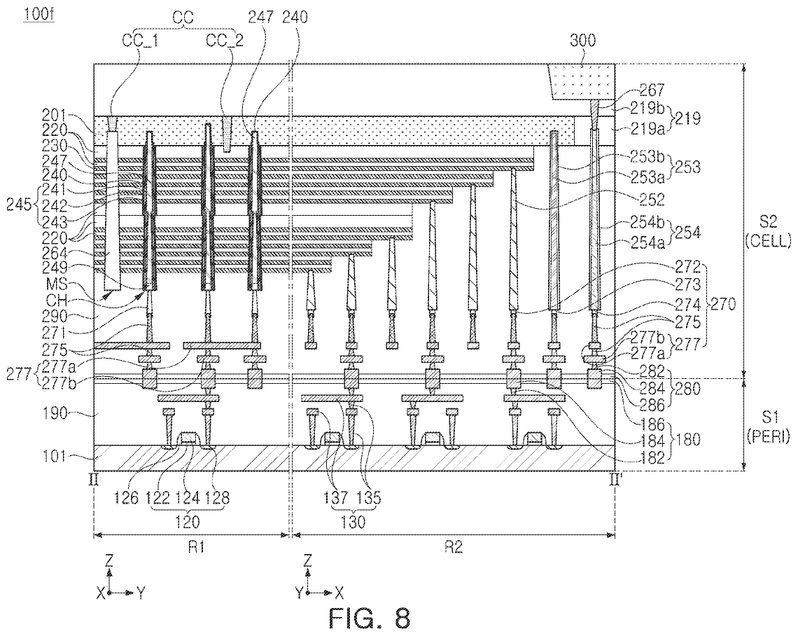

FIG. 8 is a schematic cross-sectional view of a semiconductor device 100f. FIG. 8 illustrates a portion corresponding to those of FIG. 2C.

Referring to FIG. 8, in the semiconductor device 100f, an upper surface of a second substrate 201 may not be curved. For example, the upper surface of the second substrate 201 may be parallel to an upper surface of a first substrate 101. Uppermost ends of channel structures CH may be located on the same level, but are not limited thereto. For example, lengths of which protrusions 240a protrude from the channel structures CH may be substantially be equal to each other, and an upper surface of a channel layer 240 may have a constant level. The upper surface of the second substrate 201 being parallel to the upper surface of the first substrate 101 may be independent of the upper surface of the channel layer 240 having a constant level. For example, when the upper surface of the second substrate 201 has a curved structure, the upper surface of the channel layer 240 may have a constant level. Also, when the upper surface of the second substrate 201 does not have a curved structure and is parallel to the upper surface of the first substrate 101, the upper surface of the channel layer 240 may not have a constant level. An upper surface of a source contact plug 253 may be located on a level, equal to the upper surface of the channel layer 240, but is not limited thereto.

FIG. 9A to 9I are schematic cross-sectional views illustrating a method of manufacturing a semiconductor device. FIGS. 9A to 9I illustrate portions corresponding to those of FIG. 2C.

Referring to FIG. 9A, a first semiconductor structure S1 including circuit elements 120, a lower interconnection structure 130, a lower bonding structure 180, and a lower capping layer 190, forming a peripheral circuit region PERI on a first substrate 101, may be formed.

First, device isolation layers may be formed in the first substrate 101, and a circuit gate dielectric layer 122 and a circuit gate electrode 124 may be sequentially formed on the first substrate 101. The device isolation layers may be formed by, for example, a shallow trench isolation (STI) process. The circuit gate dielectric layer 122 may be formed on the first substrate 101, and the circuit gate electrode 124 may be formed on the circuit gate dielectric layer 122. The circuit gate dielectric layer 122 and the circuit gate electrode 124 may be formed using atomic layer deposition (ALD) or chemical vapor deposition (CVD). The circuit gate dielectric layer 122 may be formed of silicon oxide, and the circuit gate electrode 124 may be formed of at least one of polycrystalline silicon or a metal silicide layer, but is not limited thereto. Next, spacer layers 126 may be formed on both sidewalls of the circuit gate dielectric layer 122 and both sidewalls of the circuit gate electrode 124, and impurities may be implanted into an active region of the first substrate 101 on both sides of the circuit gate electrode 124, to form source/drain regions 128.

Lower contact plugs 135 of the lower interconnection structure 130 may be prepared by forming a portion of the lower capping layer 190, etching and removing the portion of the lower capping layer 190, and filling the removed portion of the lower capping layer 190 with a conductive material. Lower interconnection lines 137 may be formed by, for example, depositing a conductive material and then patterning the same.

A lower bonding via 182 of the lower bonding structure 180 may be prepared by forming a portion of the lower capping layer 190, etching and removing the portion of the lower capping layer 190, and filling the removed portion of the lower capping layer 190 with a conductive material. A lower bonding pad 184 may be formed by, for example, depositing a conductive material and then patterning the same. The lower bonding structure 180 may be formed by, for example, a deposition process or a plating process. A lower bonding insulating layer 186 may be prepared by forming the lower bonding pad 184 to cover portions of upper and side surfaces of the lower bonding pad 184 and then performing a planarization process until the upper surface of the lower bonding pad 184 is exposed.

The lower capping layer 190 may include a plurality of insulating layers. The lower capping layer 190 may be a portion in the forming the lower interconnection structure 130 and a portion in the forming the lower bonding structure 180, respectively. Therefore, the first semiconductor structure S1 serving as the peripheral circuit region PERI may be formed.

Referring to FIG. 9B, a process of manufacturing the second semiconductor structure S2 may be started.

First, a lower stack structure may be formed by alternately stacking sacrificial insulating layers 218 and interlayer insulating layers 220 on a base substrate 200, and an upper stack structure may be formed by alternately stacking the sacrificial insulating layers 218 and the interlayer insulating layers 220.

Next, channel structures CH passing through a stack structure of the sacrificial insulating layers 218 and the interlayer insulating layers 220 may be formed. In a region corresponding to a separation region MS (see FIG. 2A), a separation opening TS passing through the stack structure of the sacrificial insulating layers 218 and the interlayer insulating layers 220 may be formed.

The base substrate 200 may include a semiconductor material, for example, a group IV semiconductor, a group III-V compound semiconductor, or a group II-VI compound semiconductor. The base substrate 200 may be provided to control a thickness of a second substrate 201 in a process of removing the base substrate 200, which will be described later.

Portions of the sacrificial insulating layers 218 may be replaced with gate electrodes 230 (see FIG. 2C) by a subsequent process. The sacrificial insulating layers 218 may be formed of a material, different from that of the interlayer insulating layers 220, and may be formed of a material that may be etched with etch selectivity for the interlayer insulating layers 220 under specific etching conditions. For example, the interlayer insulating layer 220 may be formed of at least one of silicon oxide or silicon nitride, and the sacrificial insulating layers 218 may be formed of a material selected from silicon, silicon oxide, silicon carbide, and silicon nitride, different from the material of the interlayer insulating layer 220. In some implementations, the interlayer insulating layers 220 may not all have the same thickness. Thicknesses of and the number of layers forming the interlayer insulating layers 220 and the sacrificial insulating layers 218 may be variously changed from those illustrated.

A photolithography process and an etching process for the sacrificial insulating layers 218 using a mask layer may be repeated such that upper sacrificial insulating layers 218 extend shorter than lower sacrificial insulating layers 218 in a second region R2. Therefore, the sacrificial insulating layers 218 may form a stepped structure in predetermined units.

Vertical sacrificial structures may be formed to pass through the lower stack structure. The vertical sacrificial structures may be prepared by anisotropically etching the lower stack structure of the sacrificial insulating layers 218 and the interlayer insulating layers 220 using the mask layer, and may be prepared by forming lower channel holes having hole shapes and then filling the same. At least portions of the vertical sacrificial structures may be prepared to recess the base substrate 200 to have different depths, but are not limited thereto. The vertical sacrificial structures may include a semiconductor material such as polycrystalline silicon. In some implementations, the vertical sacrificial structures may include at least one of silicon oxide, silicon nitride, or silicon oxynitride, respectively. After forming the vertical sacrificial structures, the upper stack structure of the sacrificial insulating layers 218 and the interlayer insulating layers 220 may be formed on the lower stack structure and the vertical sacrificial structure.

Next, an upper capping layer 290 covering the stack structure of the sacrificial insulating layers 218 and the interlayer insulating layers 220 may be partially formed.

The channel structures CH may be formed by forming upper holes on the vertical sacrificial structure, removing the vertical sacrificial structure to form channel holes having hole shapes, and filling the channel holes with a plurality of layers. The plurality of layers may include a channel dielectric layer 245, a channel layer 240, a channel filling insulating layer 247, and a channel pad 249. Upper channel holes of the channel holes may be formed by anisotropically etching the upper stack structure of the sacrificial insulating layers 218 and the interlayer insulating layers 220 using a separate mask layer. Lower channel holes of the channel holes may be formed by removing the vertical sacrificial structures exposed through the upper channel holes.

Due to a height of the stack structure, sidewalls of the channel structures CH may not be perpendicular to an upper surface of the base substrate 200. The channel structures CH may be formed to recess a portion of the base substrate 200.

The channel dielectric layer 245 may be formed to have a uniform thickness. In this operation, all or a portion of the channel dielectric layer 245 may be formed, and a portion extending perpendicularly to the second substrate 201 along the channel structures CH (see FIG. 2C) may be formed in this operation. The channel layer 240 may be formed on the channel dielectric layer 245 in the channel structures CH. The channel filling insulating layer 247 may be formed to fill the channel structures CH, and may be an insulating material. The channel pad 249 may be formed of a conductive material, and may be formed of, for example, polycrystalline silicon.

Referring to FIG. 9C, gate electrodes 230 may be formed by removing the sacrificial insulating layers 218 (in FIG. 9B) through the separation opening TS (in FIG. 9B). A separation region MS may be formed in the separation opening TS (in FIG. 9B).

Tunnel portions may be formed by removing the sacrificial insulating layers 218 through the separation opening TS (in FIG. 9B), and the gate electrodes 230 may be formed by filling the tunnel portions with a conductive material. The conductive material may include a metal, polycrystalline silicon, or a metal silicide material. After forming the gate electrodes 230, the conductive material deposited in the separation opening TS may be removed by an additional process, and then the separation region MS may be formed by filling an insulating material and a conductive material.

Referring to FIG. 9D, an upper interconnection structure 270 including gate contact plugs 252, source contact plugs 253, peripheral contact plugs 254, and channel contact plugs 271 may be formed, and an upper bonding structure 280 may be formed.

In a first region R1, channel contact plugs 271 may be formed to be connected to the channel structures CH. In the second region R2, the gate contact plugs 252 may be formed to be connected to the gate electrodes 230, and the source contact plugs 253 and the peripheral contact plugs 254 may be formed to be connected to the base substrate 200. The gate contact plugs 252, the source contact plugs 253, and the peripheral contact plugs 254 may be formed to have different depths, but may be prepared by forming contact holes at the same time using an etch stop layer or the like, and then filling the same with a conductive material. In some implementations, a portion of the gate contact plugs 252, the source contact plugs 253, and the peripheral contact plugs 254 may be formed in different processes.

Contact studs 272, 273, and 274 may be formed to be connected to the gate contact plugs 252, the source contact plugs 253, and the peripheral contact plugs 254, respectively. Upper contact plugs 275 may be formed on the contact studs 272, 273, and 274, and may connect upper interconnection lines 277 to each other vertically.

Next, an upper bonding structure 280 may be formed in a similar manner to the formation of the lower bonding structure 180. Therefore, a second semiconductor structure S2 serving as a memory cell region CELL may be formed. During the manufacturing process of the semiconductor device, the memory cell region CELL may further include the base substrate 200.

Referring to FIG. 9E, the first semiconductor structure S1 serving as the peripheral circuit region PERI and the second semiconductor structure S2 serving as the memory cell region CELL may be bonded.

The peripheral circuit region PERI and the memory cell region CELL may be connected by bonding the lower bonding pad 184 and the upper bonding pad 284 by pressing. The peripheral circuit region PERI and the memory cell region CELL may be connected by bonding the lower bonding insulating layer 186 and the upper bonding insulating layer 286 by pressing. The memory cell region CELL on the peripheral circuit region PERI may be turned over and bonded such that the upper bonding pad 284 faces downward, e.g., along the −Z direction. The peripheral circuit region PERI and the memory cell region CELL may be directly bonded without an intervening adhesive, such as a separate adhesive layer.

Referring to FIG. 9F, the base substrate 200, and the channel dielectric layer 245 on the channel structure CH may be removed. First, the base substrate 200 may be removed. A portion of the base substrate 200 may be removed from an upper surface thereof by a polishing process such as a grinding process, and a remaining portion of the base substrate 200 may be removed by an etching process such as wet etching and/or dry etching. Alternatively, the base substrate 200 may be removed by an etching process. In a region from which the base substrate 200 is removed, the source contact plug 253, the peripheral contact plug 254, and the channel structures CH may protrude.

Next, the channel dielectric layer 245 on the channel structure CH may be removed. The channel dielectric layer 245 may be removed using a photolithography process and an etching process such as wet etching and/or dry etching. For this reason, the channel layer 240 may be in contact with the second substrate 201, when a subsequent process is performed.

Referring to FIG. 9G, a second substrate 201 may be formed.

The second substrate 201 may be formed by depositing N-type doped polysilicon on the upper capping layer 290 and the uppermost interlayer insulating layer 220, in a region other than the peripheral contact plug 294 in the first region R1 and the second region R2, but is not limited thereto, and may be formed by depositing P-type doped polysilicon. For example, the second substrate 201 may be formed outside a region in which the peripheral contact plug 294 exists by using a mask layer. The second substrate 201 may be formed to cover the channel structures CH and the separation region MS. The second substrate 201 may be formed along the protruding channel layer 240, but is not limited thereto. Due to this, the second substrate 201 and the channel layer 240 may be electrically connected.

Referring to FIG. 9H, a first upper insulating layer 219a may be formed.

The first upper insulating layer 219a may be formed on the first region R1 and the second region R2. A step difference may be formed in the first upper insulating layer 219a by the second substrate 201. Therefore, the first upper insulating layer 219a may be flattened by a polishing process such as a grinding process or a chemical mechanical polishing process. In this case, at least a portion of the upper surface of the second substrate 201 may be exposed.

Referring to FIG. 9I, separation insulating patterns CC may be formed.

The separation insulating patterns CC may separate the second substrate 201 on the separation regions MS, and may pass through the second substrate 201 between the channel structures CH, to separate the second substrate 201. Therefore, a process of forming an insulating region separating a string select line SSL (see FIG. 2E) and a ground select line GSL (see FIG. 2E) among the gate electrodes 230 may be omitted. Therefore, a semiconductor device having an improved degree of integration and improved electrical characteristics as well as reducing process difficulty may be provided.

Next, referring to FIG. 2C, a second upper insulating layer 219b, a peripheral contact via 267, and a conductive pad 300 may be formed. The peripheral contact via 267 may be prepared by forming a via hole passing through a portion of the upper insulating layer 219a and then filling the via hole with a conductive material. The conductive pad 300 may be formed by partially removing the second upper insulating layer 219b and then filling the same with a conductive material. In this manner, the semiconductor device of FIGS. 1 to 2E may be manufactured.

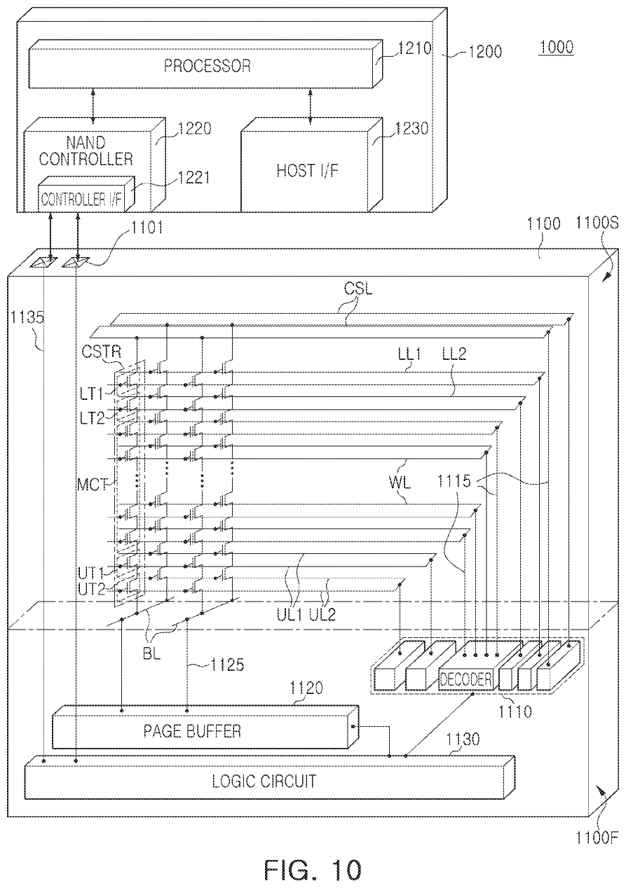

FIG. 10 is a view schematically illustrating a data storage system 1000 including a semiconductor device 1100. Referring to FIG. 10, the data storage system 1000 includes the semiconductor device 1100, and a controller 1200 electrically connected to the semiconductor device 1100. The data storage system 1000 may be a storage device including the semiconductor device 1100 as a single semiconductor device or a plurality of semiconductor devices, or an electronic device including the storage device. For example, the data storage system 1000 may be a solid-state drive device (SSD), a universal serial bus (USB), a computing system, a medical device, or a communication device, including the semiconductor device 1100 as a single semiconductor device or a plurality of semiconductor devices.

The semiconductor device 1100 may be a non-volatile memory device, for example, a NAND flash memory device according to any of the examples described above with reference to FIGS. 1 to 2E. The semiconductor device 1100 may include a first semiconductor structure 1100F, and a second semiconductor structure 1100S on the first semiconductor structure 1100F. In some implementations, the first semiconductor structure 1100F may be disposed next to the second semiconductor structure 1100S. The first semiconductor structure 1100F may be a peripheral circuit structure including a decoder circuit 1110, a page buffer 1120, and a logic circuit 1130. The second semiconductor structure 1100S may be a memory cell structure including bit lines BL, a common source line CSL, word lines WL, first and second upper gate lines UL1 and UL2, first and second lower gate lines LL1 and LL2, and memory cell strings CSTR between each of the bit lines BL and the common source line CSL.

In the second semiconductor structure 1100S, each of the memory cell strings CSTR may include lower transistors LT1 and LT2 adjacent to the common source line CSL, upper transistors UT1 and UT2 adjacent to each of the bit lines BL, and a plurality of memory cell transistors MCT disposed between each of the lower transistors LT1 and LT2 and each of the upper transistors UT1 and UT2. The number of lower transistors LT1 and LT2 can be different from the number of upper transistors UT1 and UT2. Moreover, the number of lower transistors and the number of upper transistors can be different than what is shown here.

In some implementations, each of the upper transistors UT1 and UT2 may include a string select transistor, and each of the lower transistors LT1 and LT2 may include a ground select transistor. The lower gate lines LL1 and LL2 may be gate electrodes of the lower transistors LT1 and LT2, respectively. The word lines WL may be gate electrodes of the memory cell transistors MCT, and the upper gate lines UL1 and UL2 may be gate electrodes of the upper transistors UT1 and UT2, respectively.

In some implementations, the lower transistors LT1 and LT2 may include a lower erase control transistor LT1 and a ground select transistor LT2, connected in series. The upper transistors UT1 and UT2 may include a string select transistor UT1 and an upper erase control transistor UT2, connected in series. At least one of the lower erase control transistor LT1 or the upper erase control transistor UT2 may be used for an erase operation of erasing data stored in the memory cell transistors MCT using a gate-induced-drain-leakage (GIDL) phenomenon.

The common source line CSL, the first and second lower gate lines LL1 and LL2, the word lines WL, and the first and second upper gate lines UL1 and UL2 may be electrically connected to the decoder circuit 1110 through first connection interconnections 1115 extending from the first semiconductor structure 1100F into the second semiconductor structure 1100S. The bit lines BL may be electrically connected to the page buffer 1120 through second connection interconnections 1125 extending from the first semiconductor structure 1100F into the second semiconductor structure 1100S.

In the first semiconductor structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through input/output connection interconnections 1135 extending from the first semiconductor structure 1100F into the second semiconductor structure 1100S.

The controller 1200 may include a processor 1210, a NAND controller 1220, and a host interface 1230. In some implementations, the data storage system 1000 may include a plurality of semiconductor devices 1100, and in this case, the controller 1200 may control the plurality of semiconductor devices 1100.

The processor 1210 may control an overall operation of the data storage system 1000 including the controller 1200. The processor 1210 may operate according to a predetermined firmware, and may access to the semiconductor device 1100 by controlling the NAND controller 1220. The NAND controller 1220 may include a NAND interface 1221 processing communications with the semiconductor device 1100. A control command for controlling the semiconductor device 1100, data to be written to the memory cell transistors MCT of the semiconductor device 1100, data to be read from the memory cell transistors MCT of the semiconductor device 1100, or the like may be transmitted through the NAND interface 1221. The host interface 1230 may provide a communication function between the data storage system 1000 and an external host. When a control command is received from the external host through the host interface 1230, the processor 1210 may control the semiconductor device 1100 in response to the control command.

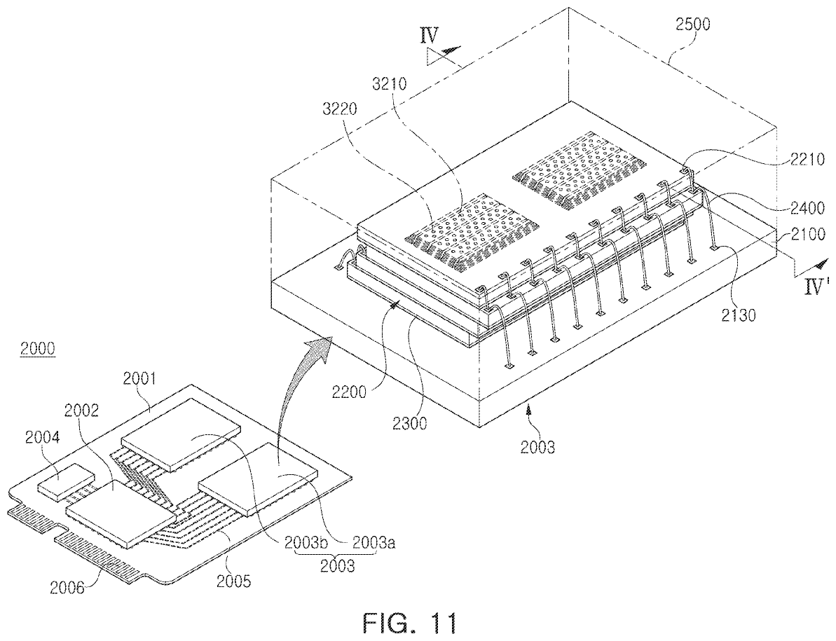

FIG. 11 is a perspective view schematically illustrating a data storage system 2000 including a semiconductor package 2003. The data storage system 2000 includes a main substrate 2001, a controller 2002 mounted on the main substrate 2001, at least one semiconductor package 2003, and a DRAM 2004. The semiconductor package 2003 and the DRAM 2004 may be connected to the controller 2002 by wiring patterns 2005 formed on the main substrate 2001.

The main substrate 2001 may include a connector 2006 including a plurality of pins, which may be coupled to an external host. The number and an arrangement of the plurality of pins in the connector 2006 may vary according to a communication interface between the data storage system 2000 and the external host. In some implementations, the data storage system 2000 may be communicated with the external host according to any one interface of a universal serial bus (USB), peripheral component interconnect express (PCI-Express), serial advanced technology attachment (SATA), M-Phy for universal flash storage (UFS), or the like. In some implementations, the data storage system 2000 may be operated by power supplied from the external host through the connector 2006. The data storage system 2000 may further include a power management integrated circuit (PMIC) distributing power, supplied from the external host, to the controller 2002 and the semiconductor package 2003.

The controller 2002 may write data to the semiconductor package 2003 or read data from the semiconductor package 2003, and may improve an operation speed of the data storage system 2000.

The DRAM 2004 may be a buffer memory reducing a difference in speed between the semiconductor package 2003, which may be a data storage space, and the external host. The DRAM 2004 included in the data storage system 2000 may also operate as a type of cache memory, and may provide a space temporarily storing data in a control operation on the semiconductor package 2003. When the DRAM 2004 is included in the data storage system 2000, the controller 2002 may further include a DRAM controller controlling the DRAM 2004 in addition to a NAND controller controlling the semiconductor package 2003.

The semiconductor package 2003 may include first and second semiconductor packages 2003a and 2003b, spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on a lower surface of each of the semiconductor chips 2200, a connection structure 2400 electrically connecting each of the semiconductor chips 2200 and the package substrate 2100, and a molding layer 2500 covering the semiconductor chips 2200 and the connection structure 2400 on the package substrate 2100.

The package substrate 2100 may be a printed circuit board including package upper pads 2130. Each of the semiconductor chips 2200 may include an input/output pad 2210. The input/output pad 2210 may correspond to the input/output pad 1101 of FIG. 10, and may be a region including the conductive pad 300 of FIG. 2A. Each of the semiconductor chips 2200 may include gate stack structures 3210 and channel structures 3220. Each of the semiconductor chips 2200 may include the semiconductor device described above with reference to FIGS. 1 to 8.

In some implementations, the connection structure 2400 may be a bonding wire electrically connecting the input/output pad 2210 and the upper package pads 2130. Therefore, in each of the first and second semiconductor packages 2003a and 2003b, the semiconductor chips 2200 may be electrically connected to each other by a bonding wire process, and may be electrically connected to the package upper pads 2130 of the package substrate 2100. In some implementations, in each of the first and second semiconductor packages 2003a and 2003b, the semiconductor chips 2200 may be electrically connected to each other by a connection structure including a through silicon via (TSV), instead of a connection structure 2400 by a bonding wire process.

In some implementations, the controller 2002 and the semiconductor chips 2200 may be included in one package. In some implementations, the controller 2002 and the semiconductor chips 2200 may be mounted on a separate interposer substrate, different from the main substrate 2001, and the controller 2002 and the semiconductor chips 2200 may be connected to each other by a wiring formed on the interposer substrate.

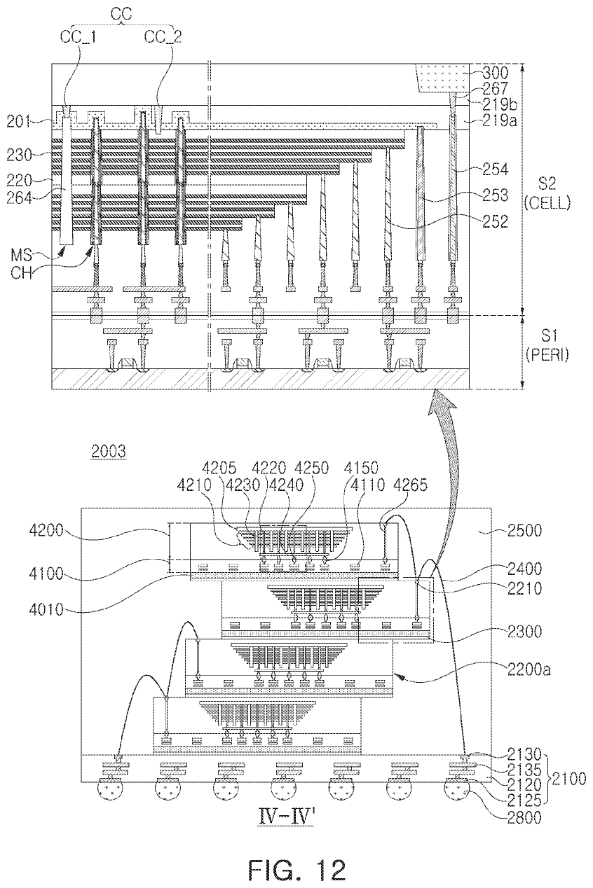

FIG. 12 is a cross-sectional view schematically illustrating the semiconductor package 2003 of FIG. 11.

FIG. 12 illustrates the semiconductor package 2003 of FIG. 11, and illustrates a region taken along line IV-IV′ of the semiconductor package 2003 of FIG. 11.

Referring to FIG. 12, in the semiconductor package 2003, the package substrate 2100 may be a printed circuit board. The package substrate 2100 may include a package substrate body portion 2120, package upper pads 2130 (refer to FIG. 11) disposed on an upper surface of the package substrate body portion 2120, lower pads 2125 disposed on a lower surface of the package substrate body portion 2120 or exposed from the lower surface, and internal interconnections 2135 electrically connecting the upper pads 2130 and the lower pads 2125 in the package substrate body portion 2120. The upper pads 2130 may be electrically connected to the connection structures 2400. The lower pads 2125 may be connected to the wiring patterns 2005 of the main substrate 2001 of the data storage system 2000, as illustrated in FIG. 11, through conductive connection portions 2800.

In the semiconductor package 2003, semiconductor chips 2200a may include a semiconductor substrate 4010, a first semiconductor structure 4100 on the semiconductor substrate 4010, and a second semiconductor structure 4200 on the first semiconductor structure 4100 and bonded to the first semiconductor structure 4100 by wafer bonding.

The first semiconductor structure 4100 may include a peripheral circuit region including a peripheral wiring 4110 and a lower junction structure 4150. The second semiconductor structure 4200 may include a common source line 4205, a gate stack structure 4210 between the common source line 4205 and the first semiconductor structure 4100, channel structures 4220 and an isolation structure 4230, passing through the gate stack structure 4210, and an upper junction structure 4250 electrically connected to word lines of the channel structures 4220 and the gate stack structure 4210, respectively. For example, the upper junction structure 4250 may be electrically connected to the word lines of the channel structures 4220 and the gate stack structure 4210, respectively, through bit lines 4240 electrically connected to the channel structures 4220, and gate contact plugs 252 (see FIG. 2C) may be electrically connected to the word lines. The lower junction structure 4150 of the first semiconductor structure 4100 and the upper junction structure 4250 of the second semiconductor structure 4200 may be bonded while contacting each other. Bonded portions of the lower junction structure 4150 and the upper junction structure 4250 may be formed of, for example, copper (Cu).

As illustrated in the enlarged view, the second semiconductor structure 4200 may further include separation insulating patterns CC. In each of the semiconductor chips 2200a, a second substrate 201 may be separated by first separation insulating patterns CC_1 passing through the second substrate 201 and connected to the separation regions MS, and second separation insulating patterns CC_2 disposed between the channel structures CH and passing through the second substrate 201.

Each of the semiconductor chips 2200a may further include input/output pads 2210 and input/output connection wires 4265 below the input/output pads 2210. An input/output connection wire 4265 may be electrically connected to portions of the gate stack structures 4210. An input/output pad 2210 may be a region including the conductive pad 300.

The semiconductor chips 2200a of FIG. 12 may be electrically connected to each other by connection structures 2400 in a bonding wire form. In some implementations, semiconductor chips in a semiconductor package, such as the semiconductor chips 2200a of FIG. 12, may be electrically connected to each other by a connection structure including a through-electrode (TSV).

A semiconductor device having improved electrical characteristics and reliability and a data storage system including the same may be provided by disposing separation insulating patterns passing through a second substrate to separate the second substrate.

Various advantages and effects of the present disclosure are not limited to the above, and will be more easily understood in the process of describing specific examples of the present disclosure. While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a claimed combination can in some cases be excised from the combination, and the claimed combination may be directed to a subcombination or variation of a subcombination.

While various example have been illustrated and described above, it will be apparent to those skilled in the art that modifications and variations could be made without departing from the scope of the present disclosure as defined by the appended claims.

What is claimed is:

1. A semiconductor device comprising:
a first semiconductor structure comprising a first substrate, circuit elements on the first substrate, a lower interconnection structure electrically connected to the circuit elements, and a lower bonding structure electrically connected to the lower interconnection structure; and
a second semiconductor structure comprising a second substrate on the first semiconductor structure, separation insulating patterns separating the second substrate into a plurality of sections, extending in a first direction, and disposed to be spaced apart from each other in a second direction, perpendicular to the first direction, gate electrodes stacked to be spaced apart from each other in a third direction, perpendicular to the first and second directions, separation regions passing through the gate electrodes, extending in the first direction, and disposed to be spaced apart from each other in the second direction, channel structures passing through the gate electrodes, extending in the third direction, and respectively comprising a channel layer, an upper interconnection structure below the gate electrodes and the channel structures, and an upper bonding structure connected to the upper interconnection structure and bonded to the lower bonding structure,
wherein the separation insulating patterns comprise first separation insulating patterns connected to the separation regions, and second separation insulating patterns between the channel structures, and passing through the second substrate.

2. The semiconductor device of claim 1, wherein a level of at least one of an upper surface of the first separation insulating patterns is substantially equal to a level of at least one of an upper surface of the second separation insulating patterns.

3. The semiconductor device of claim 1, wherein a level of at least one of a lower surface of the first separation insulating patterns is located higher than a level of at least one of a lower surface of the second separation insulating patterns.

4. The semiconductor device of claim 1, wherein levels of lower surfaces of the second separation insulating patterns are substantially equal to or lower than a level of a lower surface of the second substrate.

5. The semiconductor device of claim 1, wherein a first width of each of the first separation insulating patterns is greater than a second width of each of the second separation insulating patterns.

6. The semiconductor device of claim 5, wherein the separation regions have a third width that is substantially equal to or greater than the first width.

7. The semiconductor device of claim 1, wherein central axes of the first separation insulating patterns and central axes of the separation regions are shifted.

8. The semiconductor device of claim 1, further comprising dummy channel structures passing through the gate electrodes and extending in the third direction,
wherein the dummy channel structures are electrically separated from the second substrate by the second separation insulating patterns.

9. The semiconductor device of claim 1, wherein an uppermost end of the channel layer is in contact with the second substrate, and each of the channel structures further comprise a channel dielectric layer between the gate electrodes and the channel layer.

10. The semiconductor device of claim 9, wherein lower surfaces of the second separation insulating patterns are on a level that is lower than an upper surface of the channel layer, and that is lower than an uppermost end of the channel dielectric layer.

11. The semiconductor device of claim 9, wherein the second separation insulating patterns at least partially vertically overlap the channel dielectric layer and are spaced apart from the channel layer.

12. The semiconductor device of claim 1, wherein an upper surface of the first separation insulating patterns and an upper surface of the second separation insulating patterns are on a level higher than an uppermost end of the channel layer.

13. The semiconductor device of claim 1, wherein an upper surface of the first separation insulating patterns and an upper surface of the second separation insulating patterns are located on a level that is substantially equal to a level of at least a portion of an upper surface of the second substrate.

14. A semiconductor device comprising:
a first semiconductor structure comprising a first substrate, circuit elements on the first substrate, a lower interconnection structure electrically connected to the circuit elements, and a lower bonding structure electrically connected to the lower interconnection structure; and
a second semiconductor structure comprising a second substrate on the first semiconductor structure, separation insulating patterns separating the second substrate, extending in a first direction, and disposed to be spaced apart from each other in a second direction, perpendicular to the first direction, gate electrodes stacked to be spaced apart from each other in a third direction, perpendicular to the first and second directions, separation regions passing through the gate electrodes, extending in the first direction, and disposed to be spaced apart from each other in the second direction, channel structures passing through the gate electrodes, extending in the third direction, and respectively comprising a channel layer, an upper interconnection structure below the gate electrodes and the channel structures, and an upper bonding structure connected to the upper interconnection structure and bonded to the lower bonding structure,
wherein the separation insulating patterns are between the channel structures, and are on the separation regions.

15. The semiconductor device of claim 14, further comprising a source contact plug extending from a level, lower than a level of a lowermost gate electrode closest to the first semiconductor structure, among the gate electrodes, into at least an internal space of the second substrate, and electrically connected to the second substrate,
wherein lowermost ends of the separation insulating patterns are on a level that is lower than a level of an uppermost end of the source contact plug.

16. The semiconductor device of claim 14, wherein the separation insulating patterns pass through the second substrate, and extend below a lower surface of the second substrate.

17. The semiconductor device of claim 14, wherein a portion of the separation insulating patterns passes through at least a portion of the separation regions, and a remaining portion of the separation insulating patterns is spaced apart from the channel layer between the channel structures.

18. The semiconductor device of claim 17, wherein the second substrate and each of the separation insulating patterns are disposed alternately in the second direction.

19. A data storage system comprising:
a semiconductor storage device comprising a first semiconductor structure comprising a first substrate and circuit elements on the first substrate; a second semiconductor structure comprising a second substrate, gate electrodes spaced apart from each other and stacked below the second substrate, and channel structures passing through the gate electrodes; and an input/output pad electrically connected to the circuit elements; and
a controller electrically connected to the semiconductor storage device through the input/output pad and controlling the semiconductor storage device,
wherein the first semiconductor structure further comprises:
a lower interconnection structure electrically connected to the circuit elements; and
a lower bonding structure connected to the lower interconnection structure,
wherein the second semiconductor structure further comprises:
separation insulating patterns separating the second substrate, extending in a first direction, and spaced apart from each other in a second direction, perpendicular to the first direction;
separation regions passing through the gate electrodes, extending in the first direction, and spaced apart from each other in the second direction;
an upper bonding structure bonded to the lower bonding structure; and
an upper interconnection structure connected to the upper bonding structure,
wherein the separation insulating patterns comprise first separation insulating patterns connected to the separation regions and second separation insulating patterns between the channel structures and passing through the second substrate.

20. The data storage system of claim 19, wherein upper surfaces of the first separation insulating patterns and upper surfaces of the second separation insulating patterns are located on a level that is substantially equal to a level of at least a portion of an upper surface of the second substrate,
and wherein lower surfaces of the second separation insulating patterns are located on a level that is lower than a lower surface of the second substrate.
